(19) United States
(12) Patent Application Publication
(10) Pub. No.: US 2024/0234636 A1
(43) Pub. Date: Jul. 11, 2024

(54) DISPLAY DEVICE AND MANUFACTURING METHOD THEREOF

(71) Applicant: Samsung Display Co., LTD., Yongin-si (KR)

(72) Inventors: Hyun Eok SHIN, Yongin-si (KR); Joon Yong PARK, Yongin-si (KR); Ju Hyun LEE, Yongin-si (KR)

(73) Assignee: Samsung Display Co., LTD., Yongin-si (KR)

(21) Appl. No.: 18/502,119

(22) Filed: Nov. 6, 2023

(30) Foreign Application Priority Data
Jan. 6, 2023 (KR) 10-2023-0002434

(51) Int. Cl. H01L 33/40; H01L 25/07; H01L 25/16; H01L 33/62

(52) U.S. Cl. CPC H01L 33/40; H01L 25/073; H01L 25/167; H01L 33/62; H01L 2933/0066

(57) ABSTRACT

A display device including a substrate, and a first light emitting element, a second light emitting element, and a third light emitting element that are disposed on the substrate, each of the light emitting elements includes a first electrode, a light emitting layer, and a second electrode, the first electrode has a first metal layer, at least one inorganic layer, at least one etch stop layer, and a second metal layer stacked on each other, and a thickness of the first electrode of the first light emitting element is different from a thickness of the first electrode of the second light emitting element.

### CROSS-REFERENCE TO RELATED APPLICATIONS

This application claims priority under 35 U.S.C. § 119 from Korean Patent Application No. 10-2023-0002434 filed on Jan. 6, 2023 in the Korean Intellectual Property Office, the entire contents of which are herein incorporated by reference.

### BACKGROUND

### 1. Technical Field

The disclosure relates to a display device having a different thickness of a first electrode for each pixel and a manufacturing method thereof.

### 2. Description of the Related Art

A light emitting display device may be a self-light emitting type of display device in which a voltage may be applied to a thin film layer including a positive electrode, a negative electrode, and a light emitting layer disposed between the two electrodes, so that electrons and holes may be recombined in the light emitting layer to emit light. The light emitting display device may be attracting attention as a next-generation display device due to advantages such as a light weight and thin shape, a wide viewing angle, a fast response speed, and low power consumption.

In a light emitting display device implementing full color, it may be necessary to increase light of different wavelengths for respective pixels having different colors, for example, red, green, and blue pixels. To this end, an optical resonance structure may be adopted in which an optical length between a reflective mirror and a transflective mirror of each pixel may be changed for each emitted wavelength.

The above information disclosed in this Background section may be only for enhancement of understanding of the background of the disclosure, and therefore it may contain information that does not constitute prior art as per 35 U.S.C. § 102.

### SUMMARY

Embodiments may be to provide a display device and a manufacturing method thereof in which a thickness of a first electrode for each pixel may be differentially implemented.

An embodiment provides a display device may include a substrate, and a first light emitting element, a second light emitting element, and a third light emitting element may be disposed on the substrate, wherein each of the light emitting elements may include a first electrode, a light emitting layer, and a second electrode, the first electrode may include a first metal layer, at least one inorganic layer, at least one etch stop layer, and a second metal layer stacked on each other, and a thickness of the first electrode of the first light emitting element may be different from a thickness of the first electrode of the second light emitting element.

The at least one inorganic layer and the at least one etch stop layer may be disposed on one another in an alternate manner.

A thickest of the first electrode of the first light emitting element, the first electrode of the second light emitting element, and the first electrode of the third light emitting element may have one of the at least one inorganic layer as an upper surface that is in direct contact with the second metal layer.

At least one of the first electrode of the first light emitting element, the first electrode of the second light emitting element, and the first electrode of the third light emitting element may have one of the at least one etch stop layer as an upper surface that is in direct contact with the second metal layer.

The display device may further include a plurality of transistors disposed on the substrate, wherein each of the plurality of transistors may be electrically connected to the first metal layer.

The second metal layer may be electrically connected to the first metal layer.

An etch rate of each of the at least one etch stop layer may be lower than an etch rate of each of the at least one inorganic layer.

Each of the at least one inorganic layer may be thicker than of each of the at least one etch stop layer.

Each of the at least one inorganic layer may include at least one of a silicon nitride (SiNₓ), a silicon oxide (SiOₓ), and a silicon oxynitride (SiOₓN_{y}).

Each of the at least one etch stop layer may include TiO₂.

The light emitting layer may include a first light emitting layer disposed in the first light emitting element, a second light emitting layer disposed in the second light emitting element, and a third light emitting layer disposed in the third light emitting element.

The first light emitting layer, the second light emitting layer, and the third light emitting layer may emit light of different colors from each other.

The first light emitting layer, the second light emitting layer, and the third light emitting layer may emit light of a same color.

At least one of the first light emitting layer, the second light emitting layer, and the third light emitting layer may be commonly disposed in each of the first light emitting element, the second light emitting element, and the third light emitting element.

The display device may further include a bank disposed between ones of the first light emitting element, the second light emitting element, and the third light emitting element, the bank partitioning a light emitting area, wherein a length of a light emitting area of each of the first light emitting element, the second light emitting element, and the third light emitting element may be in a range of about 2 μm to about 8 μm, and a width of a light emitting area of each of the first light emitting element, the second light emitting element, and the third light emitting element may be in a range of about 2 μm to about 4 μm.

Areas of the light emitting areas of the first light emitting element, the second light emitting element, and the third light emitting element may be different from each other.

An embodiment provides a method of manufacturing a display device, the method may include forming a plurality of first metal layers on a substrate, forming a stack of at least one inorganic layer and at least one etch stop layer disposed on one another in an alternate manner on the plurality of first metal layers, disposing a photoresist on a portion of the stack, and etching one of the at least one inorganic layer of a portion of the stack absent of the photoresist.

In the forming of the stack of the at least one inorganic layer and the at least one etch stop layer disposed on one another in an alternate manner on the plurality of first metal layers, one of the at least one inorganic layer may be disposed on an uppermost surface of the stack.

In the etching of the one of the at least one inorganic layer of a portion of the stack absent of the photo resist, one of the at least one etch stop layer may be disposed on an uppermost surface of the etched stack.

An etch rate of each of the at least one etch stop layer may be lower than an etch rate of each of the at least one inorganic layer.

Each of the at least one inorganic layer may be thicker than each of the at least one etch stop layer.

Each of the at least one inorganic layer may include at least of a silicon nitride (SiNₓ), a silicon oxide (SiOₓ), and a silicon oxynitride (SiOₓN_{y}).

Each of the at least one etch stop layer may include TiO₂.

The method of manufacturing the display device may further include forming a second metal layer on the stack, wherein the second metal layer may be directly connected to the first metal layer.

According to the embodiments, it may be possible to provide a display device and a manufacturing method thereof in which a thickness of a first electrode for each pixel may be differentially implemented.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 illustrates a simplified plan view of a display device according to an embodiment;

FIG. 2 illustrates a simplified schematic cross-sectional view taken along line II-II′ of FIG. 1;

FIG. 3 separately illustrates only a first electrode in the embodiment of FIG. 2;

FIGS. 4 to 9 illustrate the same schematic cross-sectional views as FIG. 3 for an embodiment;

FIG. 10 illustrates the same schematic cross-sectional view as FIG. 2 for a display device according to an embodiment;

FIG. 11 schematically illustrates a stacked structure of a light emitting element in case that thicknesses of first electrodes in respective pixels equal;

FIG. 12 schematically illustrates a stacked structure of a light emitting element in case that thicknesses of first electrodes in respective pixels may be different;

FIG. 13 illustrates a schematic cross-sectional view of a display device according to an embodiment;

FIGS. 14 to 20 illustrate processes for forming a first electrode having a different thickness for each pixel according to an embodiment; and

FIG. 21 illustrates etching of a first electrode not including an etch stop layer.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein.

It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be predisposed differently from the described order. For example, two consecutively described processes may be predisposed substantially at the same time or predisposed in an order opposite to the described order. Also, like reference numerals and/or reference characters denote like elements.

When an element, such as a layer, is referred to as being “on,” “connected to,” or “electrically connected to” another element or layer, it may be directly on, connected to, or electrically connected to the other element or layer or intervening elements or layers may be present. When, however, an element or layer is referred to as being “directly on,” “directly connected to,” or “directly electrically connected to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Further, the X-axis, the Y-axis, and the Z-axis may not be limited to three axes of a rectangular coordinate system, such as the x, y, and z axes, and may be interpreted in a broader sense. For example, the X-axis, the Y-axis, and the Z-axis may be perpendicular to one another, or may represent different directions that may not be perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items. A description that a component is “configured to” perform a specified operation may be defined as a case where the component is constructed and arranged with structural features that can cause the component to perform the specified operation.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, may not be necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be disposed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, portion, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein. Hereinafter, embodiments of the disclosure will be described with reference to accompanying drawings.

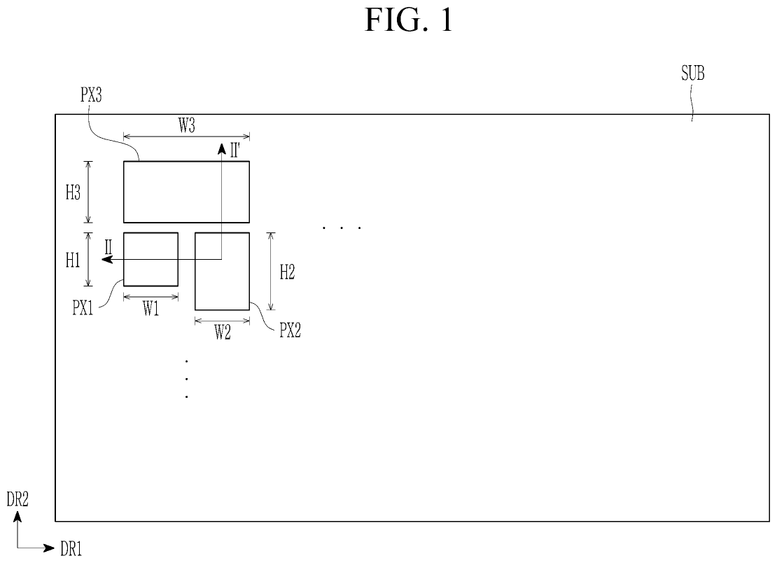

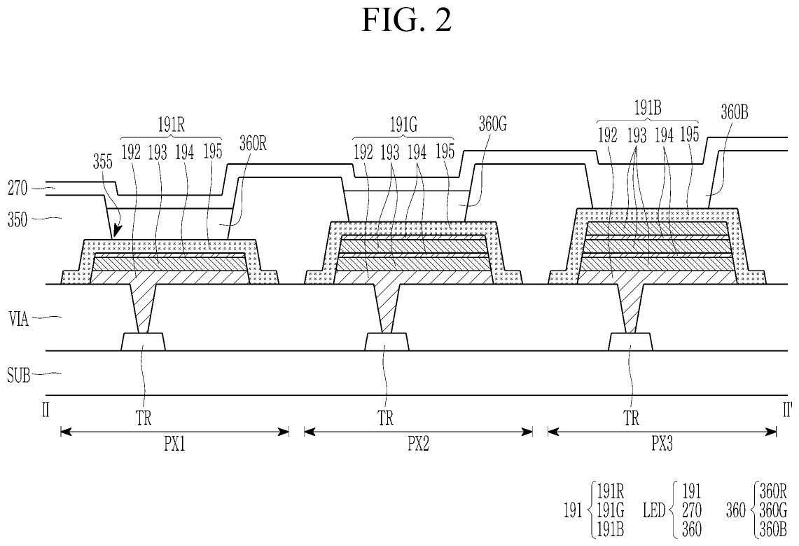

FIG. 1 illustrates a simplified plan view of a display device according to an embodiment. FIG. 2 illustrates a simplified schematic cross-sectional view taken along line II-II′ of FIG. 1. Referring to FIG. 1, the display device according to the embodiment includes a first pixel PX1, a second pixel PX2, and a third pixel PX3 disposed on a substrate SUB. Respective pixels may emit different colors. For example, the first pixel PX1 may emit red, the second pixel PX2 may emit green, and the third pixel PX3 may emit blue. Sizes of respective pixels may be different, and the size of the first pixel PX1 that emits red may be the smallest, and the size of the third pixel PX3 that emits blue may be the largest.

Depending on how high the resolution is, the size of each of the pixels may decrease. For example, a length W1 of the first pixel PX1 in a first direction DR1 may be about 2.5 μm to about 3.5 μm, and a length H1 thereof in a second direction DR2 may be about 2.2 μm to about 3.2 μm. A length W2 of the second pixel PX2 in the first direction DR1 may be about 2.7 μm to about 3.7 μm, and a length H2 thereof in the second direction DR2 may be about 2.3 μm to about 3.3 μm. A length W3 of the third pixel PX3 in the first direction DR1 may be about 6.0 μm to about 7.0 μm, and a length H3 thereof in the second direction DR2 may be about 2.2 μm to about 3.2 μm.

In case that the size of one pixel is reduced according to a high resolution, formation of a light emitting layer of each of the first pixel PX1, the second pixel PX2, and the third pixel PX3 may not readily be possible. Since the sizes of the first pixel PX1, the second pixel PX2, and the third pixel PX3 may be small, an alignment error and deposition deviation of a mask used to form each light emitting layer may increase. A fine metal mask (FMM) may be used to form the light emitting layer, and the deposition deviation due to the thickness of the fine metal mask (FMM) itself may largely increase.

The optimum resonance thicknesses of the first pixel PX1, the second pixel PX2, and the third pixel PX3 displaying respective colors may be different, and accordingly, in order to form an optimum resonance thickness for each color, an auxiliary layer may be formed by using the fine metal mask (FMM) or the like, or the light emitting layers may be formed with different thicknesses. However, in case that the size of one pixel may be reduced in a high-resolution display device, formation of an optimum resonance thickness of a pixel representing each color by using a mask as described above may not be readily possible.

Accordingly, in the display device according to the embodiment, the thicknesses of the first electrodes respectively included in the first pixel PX1, the second pixel PX2, and the third pixel PX3 may be differently formed, so that the resonance of each pixel may be controlled by the thickness difference between the first electrodes. Therefore, even in case that the size of one pixel in an ultra-high resolution display device may be reduced, it may be possible to derive the optimal resonance thickness for each pixel.

FIG. 2 illustrates a simplified schematic cross-sectional view taken along line II-II′ of FIG. 1. Referring to FIG. 2, multiple transistors TR may be disposed on the substrate SUB. Each transistor TR may include a semiconductor, a gate electrode, a source electrode, and a drain electrode. An insulating film VIA may be disposed on the transistor TR. A first electrode 191 may be disposed on the insulating film VIA. The first electrode 191 may include a first electrode 191R of the first pixel PX1, a first electrode 191G of the second pixel PX2, and a first electrode 191B of the third pixel PX3.

Each of the first electrodes 191R, 191G, and 191B may be electrically connected to the transistor TR through an opening of the insulating film VIA. Each of the first electrodes 191R, 191G, and 191B includes a first metal layer 192 in contact (e.g., in direct contact with) and electrically connected to the transistor, an inorganic layer 193 disposed as one or more layers and an etch stop layer 194 disposed as one or more layers on the first metal layer 192, and a second metal layer 195 disposed at an uppermost end of the first electrode 191 and electrically connected to and in contact with the first metal layer 192. In each pixel, the inorganic layer 193 and the etch stop layer 194 may be alternately stacked on each other, and the number of the stacks may be different for each pixel, which will be separately described later in detail.

A partition wall or bank 350 may be disposed on the first electrodes 191R, 191G, and 191B. The bank 350 includes an opening 355 overlapping a portion of each of the first electrodes 191R, 191G, and 191B, and a light emitting layer emitting light of each color may be disposed in the opening 355. A first light emitting layer 360R may be disposed in the first pixel PX1, and the first light emitting layer 360R may emit red light. A second light emitting layer 360G may be disposed in the second pixel PX2, and the second light emitting layer 360G may emit green light. A third light emitting layer 360B may be disposed in the third pixel PX3, and the third light emitting layer 360B may emit blue light. Although not shown, each of the pixels PX1, PX2, and PX3 may further include an auxiliary layer respectively disposed between the light emitting layers 360R, 360G, and 360B and the first electrodes 191R, 191G, and 191B. In the embodiment of FIG. 2, the first light emitting layer 360R, the second light emitting layer 360G, and the third light emitting layer 360B may be respectively disposed in the first pixel PX1, the second pixel PX2, and the third pixel PX3, while in other embodiments to be discussed, a common light emitting layer may be disposed in the first pixel PX1, the second pixel PX2, and the third pixel PX3. This will be described later as a separate embodiment.

A second electrode 270 may be disposed on the light emitting layer 360 and the bank 350. The second electrode 270 may be commonly disposed on the first pixel PX1, the second pixel PX2, and the third pixel PX3. The first electrode 191, the light emitting layer 360, and the second electrode 270 may form a light emitting element LED. Although not shown, a hole transport layer may be disposed between the first electrode 191 and the light emitting layer 360, and an electron transport layer may be disposed between the light emitting layer 360 and the second electrode 270. As shown in FIG. 2, the thicknesses of the first electrodes 191 disposed at the first pixel PX1, the second pixel PX2, and the third pixel PX3 may be different.

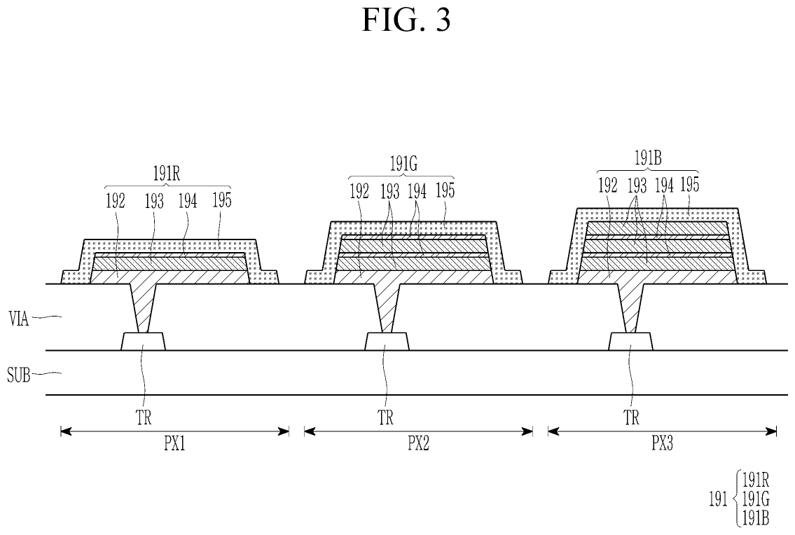

FIG. 3 separately illustrates only the first electrode 191 in the embodiment of FIG. 2. Referring to FIG. 3, the first electrode 191 includes the first metal layer 192, multiple inorganic layers 193 and etch stop layers 194 disposed on the first metal layer 192, and the second metal layer 195 located on the uppermost end of the first electrode 191 and in contact with and electrically connected to the first metal layer 192.

As shown in FIG. 3, the thicknesses of the first electrodes 191 in respective pixels may be different. The first electrode 191B of the third pixel PX3 may include the first metal layer 192, three inorganic layers 193, and two etch stop layers 194. As shown in FIG. 3, the inorganic layer 193 and the etch stop layer 194 may be alternately disposed on each other one by one. The uppermost layer of the alternately disposed layers of the first electrode 191B of the third pixel PX3 may be the inorganic layer 193. An upper surface of the uppermost inorganic layer 193 may contact (e.g., directly contact) the second metal layer 195.

The second metal layer 195 may be disposed while covering the inorganic layer 193 and the etch stop layer 194 that may be alternately stacked on each other, and may contact (e.g., directly contact) and be electrically connected to the first metal layer 192. The inorganic layer 193 and the etch stop layer 194 may include insulating materials. Accordingly, since the first metal layer 192 and the second metal layer 195 may be electrically connected to each other and are in direct contact with each other, the voltage received from the transistor may be transmitted to the second metal layer 195 through the first metal layer 192.

The thickness of the first electrode 191G of the second pixel PX2 may be thinner than that of the first electrode 191B of the third pixel PX3. As shown in FIG. 3, the first electrode 191G of the second pixel PX2 may include the first metal layer 192, two inorganic layers 193, and two etch stop layers 194. The uppermost layer of the alternately disposed layers may be the etch stop layer 194. The second metal layer 195 may be disposed on the etch stop layer 194. An upper surface of the uppermost etch stop layer 194 may contact (e.g., directly contact) the second metal layer 195. The second metal layer 195 may be disposed while covering the inorganic layer 193 and the etch stop layer 194 that may be alternately stacked on each other, and may be electrically connected to and contact (i.e., directly contact) the first metal layer 192.

The thickness of the first electrode 191R of the first pixel PX1 may be thinner than the thickness of the first electrode 191B of the third pixel PX3 and the thickness of the first electrode 191G of the second pixel PX2. As shown in FIG. 3, the first electrode 191R of the first pixel PX1 may include the first metal layer 192, the inorganic layer 193, the etch stop layer 194, and the second metal layer 195. The etch stop layer 194 may be disposed on the inorganic layer 193. The second metal layer 195 may be disposed on the etch stop layer 194. An uppermost surface of the etch stop layer 194 may contact (e.g., directly contact) the second metal layer 195. The second metal layer 195 may be disposed while covering the inorganic layer 193 and the etch stop layer 194 that may be alternately stacked on each other, and may be electrically connected to and contact (i.e., directly contact) the first metal layer 192.

The thickness of the first electrode 191 may be differently formed by varying the number of layers of the inorganic layer 193 and the etch stop layer 194 in each pixel. The thickest first electrode 191B may be configured to have a total of five layers, and may include three inorganic layers 193 and two etch stop layers 194, and the uppermost layer thereof may be the inorganic layer 193. The second thickest first electrode 191G may be configured to have a total of four layers, and may include two inorganic layers 193 and two etch stop layers 194, and the uppermost layer thereof may be the etch stop layer 194. The thinnest first electrode 191R may include a one-layer inorganic layer 193 and a single-layer etch stop layer 194, and the uppermost layer thereof may be the etch stop layer 194. However, the number of the stacked layers may be only an example, and the number of layers of the inorganic layer 193 and the etch stop layer 194 may be appropriately adjusted according to the resonance thickness required for each pixel.

The first metal layer 192 of the first electrode 191 may include one or more of calcium (Ca), ytterbium (Yb), aluminum (Al), silver (Ag), magnesium (Mg), samarium (Sm), titanium (Ti), gold (Au), and an alloy thereof. For example, the first metal layer 192 may include aluminum or an aluminum alloy. The inorganic layer 193 may include one or more of a silicon nitride (SiNₓ), a silicon oxide (SiOₓ), and a silicon oxynitride (SiOₓN_{y}). For example, the inorganic layer 193 may include SiO₂. The etch stop layer 194 may contain a material that has a lower etch rate compared to that of the inorganic layer 193. For example, the etch stop layer 194 may contain TiO₂. However, it may not be limited thereto, and the etch rate of the etch stop layer 194 may be lower than that of the inorganic layer 193, and any transparent material may be used without limitation. TiO has a low dry etch rate, and may be generally etched by an ion etching technique, so it may be suitable for use as the etch stop layer 194. The etch stop layer 194 may include a material having high etch selectivity with respect to the inorganic layer 193. As described above, since the etch stop layer 194 may include a material having a lower etch rate than that of the inorganic layer 193, multiple electrodes 191 having different stacked structures may be simultaneously formed in one process. A specific manufacturing method thereof will be described later.

A thickness of the etch stop layer 194 may be thinner than that of the inorganic layer 193. Since the etch stop layer 194 slows down the etch rate during the etching process, in case that the thickness of the etch stop layer 194 may be thicker than that of the inorganic layer 193, the process time for forming the first electrode 191 may increase. Therefore, it may not be good for the thickness of the etch stop layer 194 to be thicker than that of the inorganic layer 193.

The second metal layer 195 may include a transparent conductive oxide. For example, the second metal layer 195 may include one or more of an indium tin oxide (ITO), an indium zinc oxide (IZO), a zinc tin oxide (ZTO), a copper indium oxide (CIO), a copper zinc oxide (CZO), a gallium zinc oxide (GZO), an aluminum zinc oxide (AZO), a tin oxide (SnO₂), a zinc oxide (ZnO), and a combination thereof.

FIG. 3 illustrates the structure in which the thicknesses of the first electrodes 191 of the first pixel PX1, the second pixel PX2, and the third pixel PX3 may be all different, but this may be only an example, and in some pixels, the first electrodes 191 may have the same thickness.

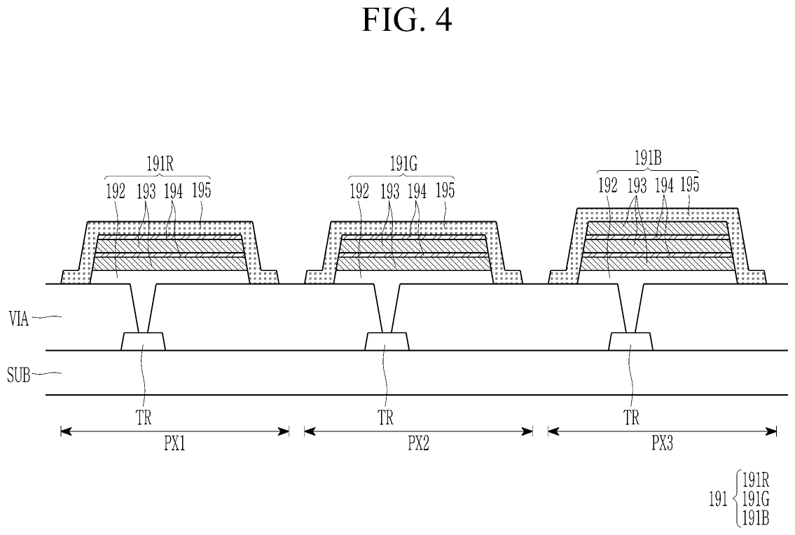

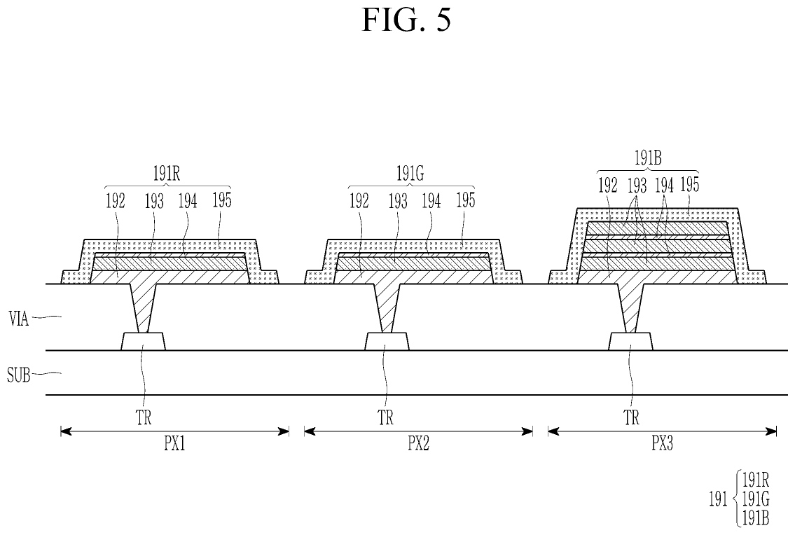

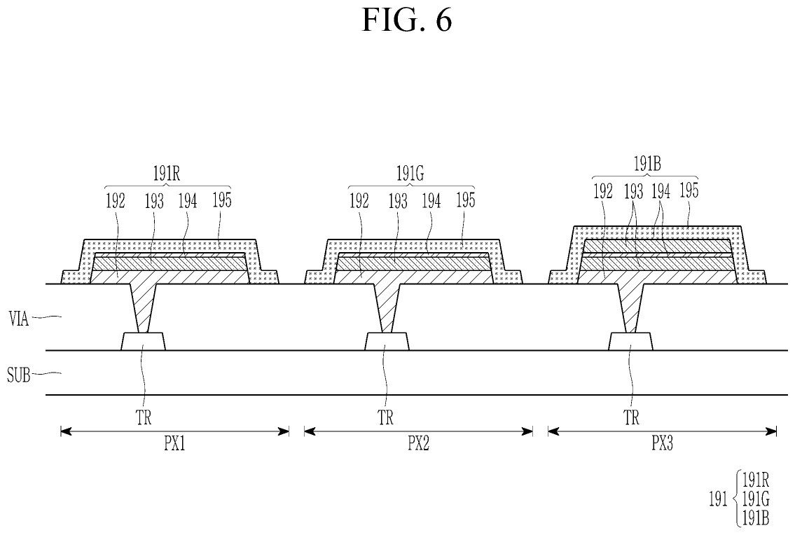

FIG. 4 illustrates an embodiment having the same schematic cross-section as FIG. 3 (i.e., along line II-II′ of FIG. 1). Referring to FIG. 4, the display device according to the embodiment may be the same as that of the embodiment of FIG. 3 except that the first electrode 191R of the first pixel PX1 and the first electrode 191G of the second pixel PX2 have the same thickness. A detailed description of the same constituent elements will be omitted. In FIG. 4, the first electrode 191R of the first pixel PX1 and the first electrode 191G of the second pixel PX2 may be shown as including two inorganic layers 193 and two etch stop layers 194, but may not be limited thereto. For example and as shown in FIG. 5, the first electrode 191R of the first pixel PX1 and the first electrode 191G of the second pixel PX2 may instead include only one-layer inorganic layer 193 and only one-layer etch stop layer 194. In FIG. 5, the first electrode 191B of the third pixel PX3 may be shown as having a configuration including the inorganic layer 193 having three layers and the etch stop layer 194 having two layers, but may not be limited thereto. For example and as shown in FIG. 6, the inorganic layer 193 may have two layers and the etch stop layer 194 may have just one layer in the first electrode 191B of the third pixel PX3.

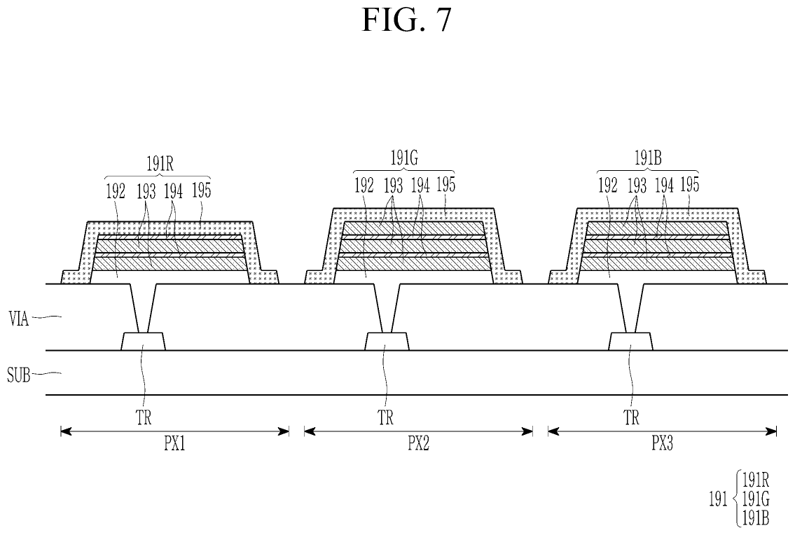

FIG. 7 illustrates an embodiment corresponding to a same schematic cross-section as that of FIG. 3 (i.e., along line II-II′ of FIG. 1). Referring to FIG. 7, the display device according to the embodiment may be the same as that of the embodiment of FIG. 3 except that the first electrode 191G of the second pixel PX2 and the first electrode 191B of the third pixel PX3 have the same thickness. A detailed description of the same constituent elements will be omitted. In FIG. 7, the first electrode 191G of the second pixel PX2 and the first electrode 191B of the third pixel PX3 may each include the inorganic layer 193 of three layers and the etch stop layer 194 of two layers, and the first electrode 191R of the first pixel PX1 may include the inorganic layer 193 of two layers and the etch stop layers 194 of two layers.

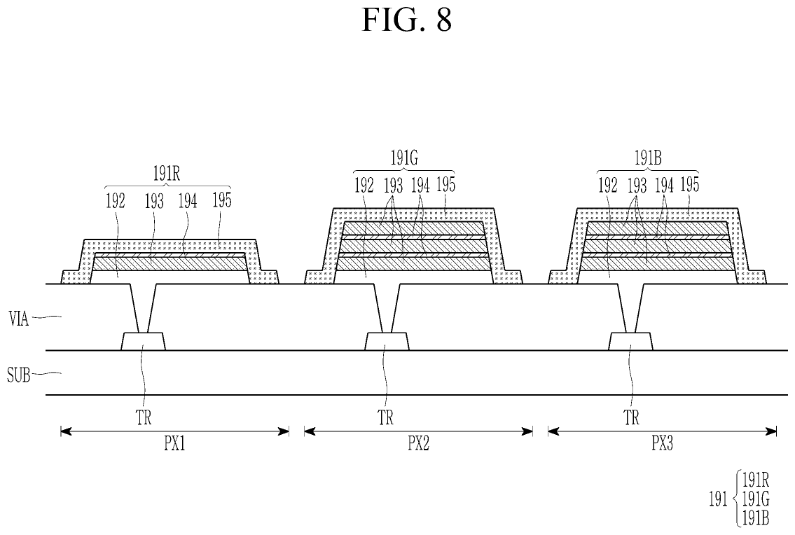

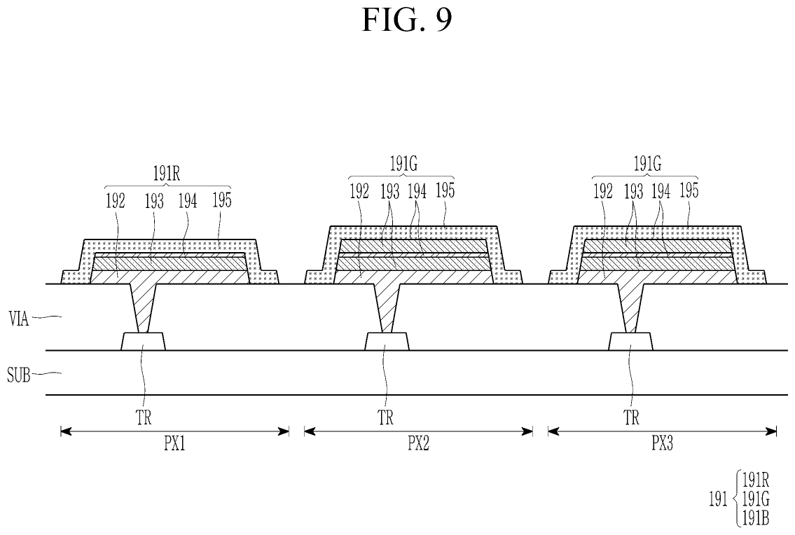

As shown in FIG. 8, the first electrode 191R of the first pixel PX1 may include one layer of the inorganic layer 193 and one layer of the etch stop layer 194. In FIG. 8, the first electrode 191G of the second pixel PX2 and the first electrode 191B of the third pixel PX3 may be shown as having a configuration including the inorganic layer 193 of three layers and the etch stop layer 194 of two layers, but may not be limited thereto. For example and as shown in FIG. 9, the inorganic layer 193 of two layers and the etch stop layer 194 of one layer may be included for each of the first electrode 191G of the second pixel PX2 and the first electrode 191B of the third pixel PX3.

In the above, various embodiments of the first electrode 191R of the first pixel PX1, the first electrode 191G of the second pixel PX2, and the first electrode 191B of the third pixel PX3 have been described above, but they may be only examples, and the disclosure may not be limited thereto. Those skilled in the art may appropriately adjust the thickness of the first electrode 191 to have a thickness optimized for resonance of each of the pixels PX1, PX2, and PX3.

In the above, as an example, the configuration in which the first electrode 191 includes maximum three layers of the inorganic layer 193 and two layers of the etch stop layer 194 has been described, but this may be only an example, and those skilled in the art may appropriately vary the number of layers of the inorganic layer 193 and the etch stop layer 194 and the thickness of each layer as needed.

As described above, since the optimum resonance thickness for each pixel may be derived by differentiating the thickness of the first electrode 191, a process of using a separate mask for each pixel of the display device may be omitted.

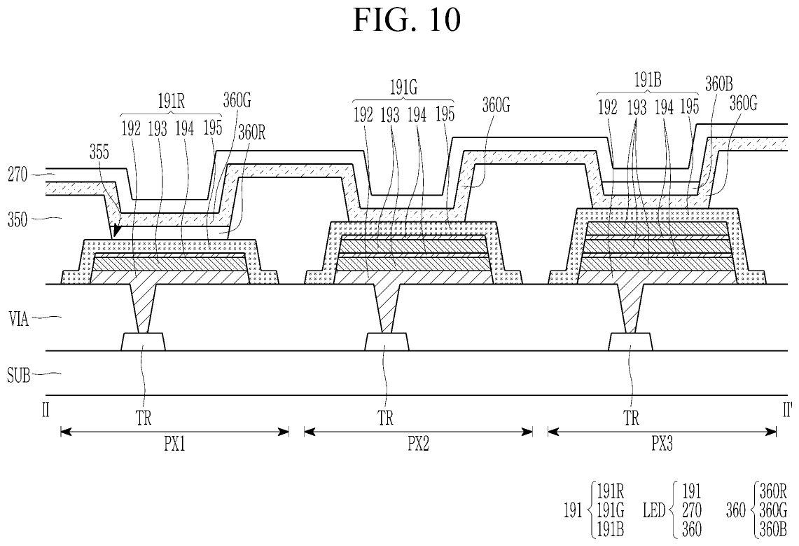

FIG. 10 illustrates the same schematic cross-sectional view as FIG. 2 (i.e., along line II-II′ of FIG. 1) for a display device according to an embodiment. Referring to FIG. 10, in the display device according to the embodiment, the second light emitting layer 360G may be commonly disposed in the first pixel PX1, the second pixel PX2, and the third pixel PX3. The first pixel PX1 may further includes the first light emitting layer 360R disposed between the second light emitting layer 360G and the first electrode 191R, and the third pixel PX3 may further include the third light emitting layer 360B disposed between the second light emitting layer 360G and the second electrode 270. For example, the first light emitting layer 360R may be a red light emitting layer, the second light emitting layer 360G may be a green light emitting layer, and the third light emitting layer may be a blue light emitting layer. In the embodiment of FIG. 10, since the second light emitting layer 360G may be commonly formed in all pixels, it may be economical because the number of masks may be reduced. In the embodiment of FIG. 10, since the thicknesses of the first electrodes 191R, 191G, and 191B in respective pixels may be different, even if the second light emitting layer 360G may be commonly disposed, an optimum thickness for resonance may be formed for each color. Referring to FIG. 10, the first pixel PX1 includes the first light emitting layer 360R overlapping the second light emitting layer 360G, and accordingly, a desired color may be emitted by a combination of the first light emitting layer 360R and the second light emitting layer 360G. Similarly, the third pixel PX3 further includes the third light emitting layer 360B overlapping the second light emitting layer 360G, and accordingly, a desired color may be emitted by a combination of the second light emitting layer 360G and the third light emitting layer 360B.

In FIG. 10, the configuration in which the second light emitting layer 360G may be commonly disposed for respective pixels has been described as an example, but this may only be an example, and the disclosure may not be limited thereto. In some embodiments, the first light emitting layer 360R or the third light emitting layer 360B may be commonly disposed, and a structure in which multiple light emitting layers may be commonly disposed in respective pixels may be also possible.

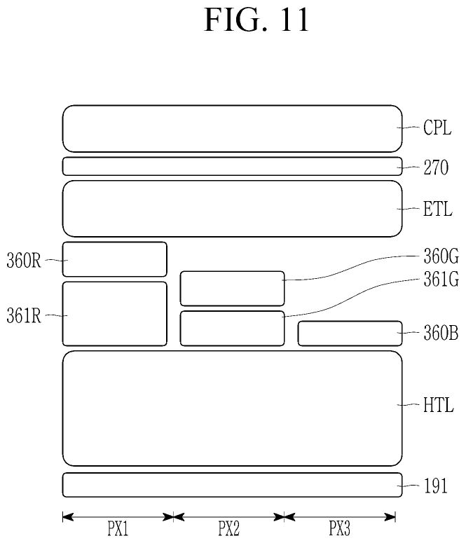

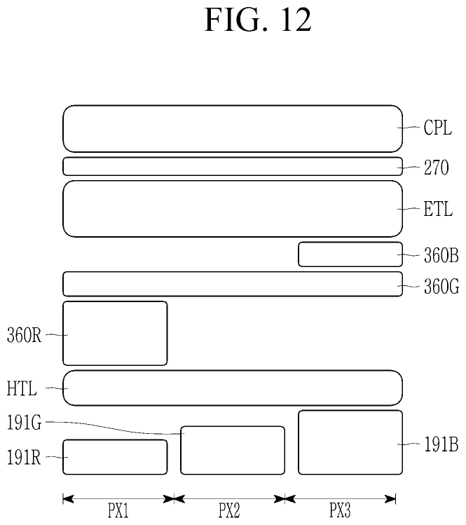

FIG. 11 schematically illustrates a stacked structure of a light emitting element in case that thicknesses of the first electrodes 191 in respective pixels may be the same, and FIG. 12 schematically illustrates a stacked structure of a light emitting element in case that the thicknesses of the first electrodes 191R, 191G, and 191B in respective pixels may be different, as in the embodiment. Referring to FIG. 11, a hole transport layer HTL may be disposed on the first electrode 191. In FIGS. 11 and 12, a configuration common to respective pixels PX1, PX2, and PX3 may be shown as one. In the embodiment of FIG. 11, the first electrode 191 and the hole transport layer HTL may be commonly disposed in respective pixels PX1, PX2, and PX3.

The first pixel PX1 may include a first auxiliary layer 361R and the first light emitting layer 360R. The second pixel PX2 may include a second auxiliary layer 361G and the second light emitting layer 360G. The third pixel PX3 may include the third light emitting layer 360B. An electron transport layer ETL may be commonly disposed on the first light emitting layer 360R, the second light emitting layer 360G, and the third light emitting layer 360B. The second electrode 270 may be disposed on the electron transport layer ETL, and a capping layer CPL may be disposed on the second electrode 270.

In the embodiment of FIG. 11 in which the thickness of the first electrode 191 in respective pixels may be constant, it may be possible to form an optimized resonance thickness for each pixel through the configuration of the first auxiliary layer 361R and the second auxiliary layer 361G. Since the resonance thicknesses required for red, green, and blue pixels may be different, the optimum resonance thickness may be obtained by controlling the thicknesses of the first light emitting layer 360R, the second light emitting layer 360G, the third light emitting layer 360B, the first auxiliary layer 361R, and the second auxiliary layer 361G. Accordingly, in the display device having the structure shown in FIG. 11, respective masks are used to form the first light emitting layer 360R, the second light emitting layer 360G, the third light emitting layer 360B, the first auxiliary layer 361R, and the second auxiliary layer 361G. The mask used at this time may be a fine metal mask, and as described above, as the pixel size decreases at high resolution, an alignment error of the mask and deposition distribution due to the thickness of the mask may have a significant effect. Even a slight change in the alignment of the mask itself has a significant effect, and even if the mask may be well aligned, precise deposition may not be performed due to deposition dispersion due to the thickness of the mask. However, the display device according to the embodiment reduces the number of masks used through the differential anode structure for each pixel, and thus a high-resolution display device may be stably manufactured.

FIG. 12 schematically illustrates a stacked structure of the light emitting device according to an embodiment of the disclosure. Referring to FIG. 12, the first electrodes 191R, 191G, and 191B may be disposed to have different thicknesses for each pixel. The thicknesses of the first electrodes 191R, 191G, and 191B illustrated in FIG. 12 may be only examples, and the disclosure may not be limited thereto. The hole transport layer HTL may be disposed on the first electrodes 191R, 191G, and 191B. In the embodiment of FIG. 12, the hole transport layer HTL may be commonly disposed in the pixels PX1, PX2, and PX3. The second light emitting layer 360G may be commonly disposed in the pixels. The second light emitting layer 360G may be commonly disposed in the first pixel PX1, the second pixel PX2, and the third pixel PX3. Accordingly, a separate mask may not be required to form the second light emitting layer 360G, and even if a mask may be used, problems caused by alignment errors or deposition dispersion may be reduced as the deposition area may be widened.

The first pixel PX1 may further include the first light emitting layer 360R. Accordingly, the first pixel PX1 may emit light of a desired color through a combination of the first light emitting layer 360R and the second light emitting layer 360G. The resonance thickness of the first pixel PX1 may be controlled through the first light emitting layer 360R.

The third pixel PX3 may further include the third light emitting layer 360B. Accordingly, the third pixel PX3 may emit light of a desired color through a combination of the third light emitting layer 360B and the second light emitting layer 360G. The resonance thickness of the third pixel PX3 may be controlled through the third light emitting layer 360B.

The electron transport layer ETL may be commonly disposed on the first light emitting layer 360R, the second light emitting layer 360G, and the third light emitting layer 360B. The second electrode 270 may be disposed on the electron transport layer ETL, and the capping layer CPL may be disposed on the second electrode 270.

In the embodiment of FIG. 12, the optimal resonance thickness for each pixel may be controlled by varying the thickness of the first electrodes 191R, 191G, and 191B. In the embodiment of FIG. 12, a mask may be used to form the first light emitting layer 360R and the third light emitting layer 360B, and a mask may also be used to form the second light emitting layer 360G according to embodiments. Compared to FIG. 11, the number of masks used in the structure of FIG. 12 may be 2 or 3, which may be less than 5 in FIG. 11, which may be economical. It may be possible to reduce problems caused by alignment errors and deposition dispersion that may occur in case that depositing a small area with a mask.

In the light emitting element and the display device including the light emitting element according to the embodiment, the thicknesses of the first electrodes 191R, 191G, and 191B may be differently formed for each pixel to control the resonance thickness for each pixel. Accordingly, the number of masks used for each pixel may be reduced, and as the size of one pixel in an ultra-high resolution display device decreases, problems in which deposition may not be accurately performed due to mask alignment errors and deposition dispersion may be solved.

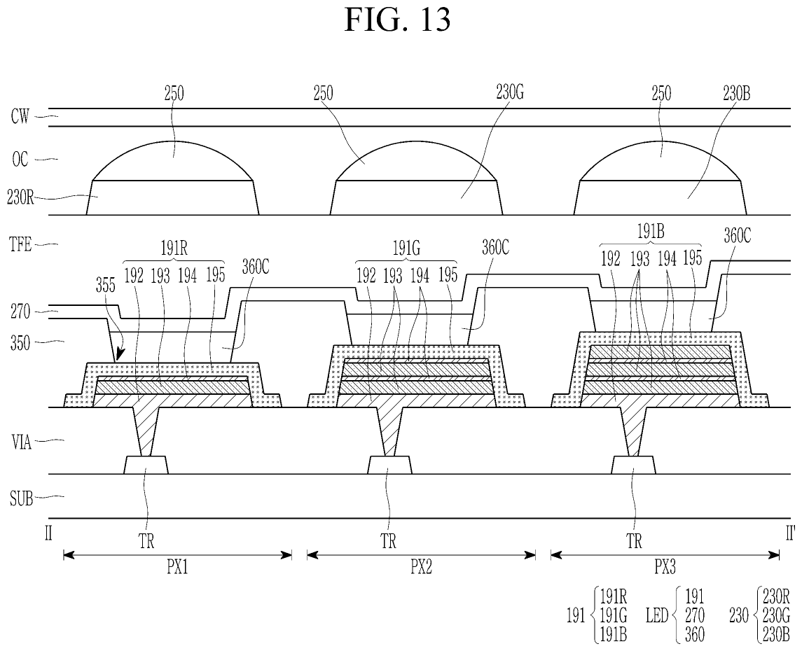

FIG. 13 illustrates a schematic cross-sectional view of a display device according to an embodiment. FIG. 13 illustrates a display device having a structure in which the light emitting elements of respective pixels emit light of the same color and the light emitted from the light emitting elements may be emitted in respective colors through a color filter. Referring to FIG. 13, the first pixel PX1, the second pixel PX2, and the third pixel PX3 include the same light emitting layer 360C. The light emitting layer 360C may have a tandem structure in which a multiple light emitting layers emitting light of different colors may be stacked on each other, and a light emitting element including the light emitting layer 360C may emit white or blue light, but may not be limited thereto. The light emitting elements of the first pixel PX1, the second pixel PX2, and the third pixel PX3 may emit light of the same color in common. Even in this embodiment, the thicknesses of the first electrodes 191R, 191G, and 191B of respective pixels may be different. Accordingly, it may be possible to control the resonance thickness for each pixel.

Referring back to FIG. 13, the second electrode 270 may be disposed on the light emitting layer 360C. An encapsulation layer TFE may be disposed on the second electrode 270. The color filter 230 may be disposed on the encapsulation layer TFE. The color filter may include a first color filter 230R, a second color filter 230G, and a third color filter 230B displaying different colors. Each color filter 230 may be disposed to overlap each light emitting element in a direction perpendicular to the substrate SUB. A lens 250 may be disposed on the first color filter 230R, the second color filter 230G, and the third color filter 230B. In some embodiments, the lens 250 may be omitted. An overcoat layer OC may be disposed on the lens 250. A cover window CW may be disposed on the overcoat layer OC.

The configuration in which the thicknesses of the first electrodes 191R, 191G, and 191B of respective pixels may be different according to the embodiment may be applied to the display device in which the light emitting elements of respective pixels emit light of different colors as well as the display device in which the light emitting elements of respective pixels emit the same color and light of different colors may be emitted by a color filter.

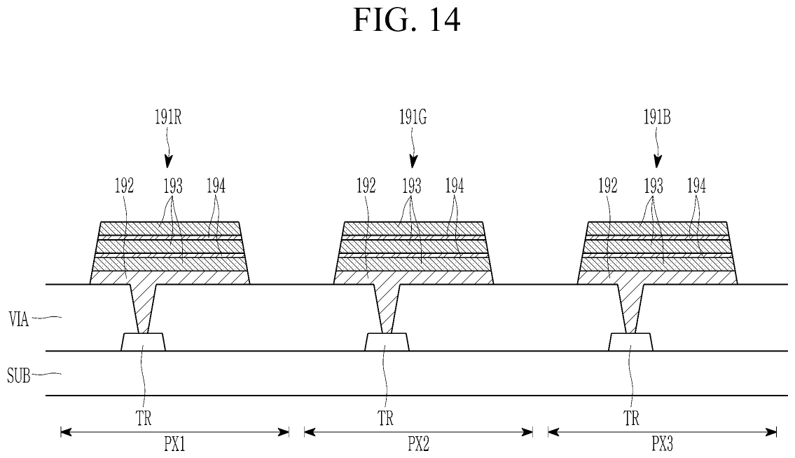

Hereinafter, a method of forming the first electrode according to the embodiment will be described in detail with reference to the drawings. FIGS. 14-20 illustrate processes for forming the first electrodes having different thickness in respective pixels according to an embodiment. Referring to FIG. 14, the inorganic layer 193 and the etch stop layer 194 may be alternately stacked on each other on the first metal layer 192. Descriptions of the first metal layer 192, the inorganic layer 193, and the etch stop layer 194 may be the same as those described above. A detailed description of the same constituent elements will be omitted. Although three inorganic layers 193 and two etch stop layers 194 may be shown in FIG. 14, those skilled in the art may freely adjust the thicknesses and quantities of the inorganic layer 193 and the etch stop layer 194 according to embodiments.

FIG. 14 shows the first electrode 191R of the first pixel, the first electrode 191G of the second pixel, and the first electrode 191B of the third pixel corresponding to respective pixels. Referring to FIG. 14, the inorganic layer 193 may be disposed as the uppermost layer of the stacked structure.

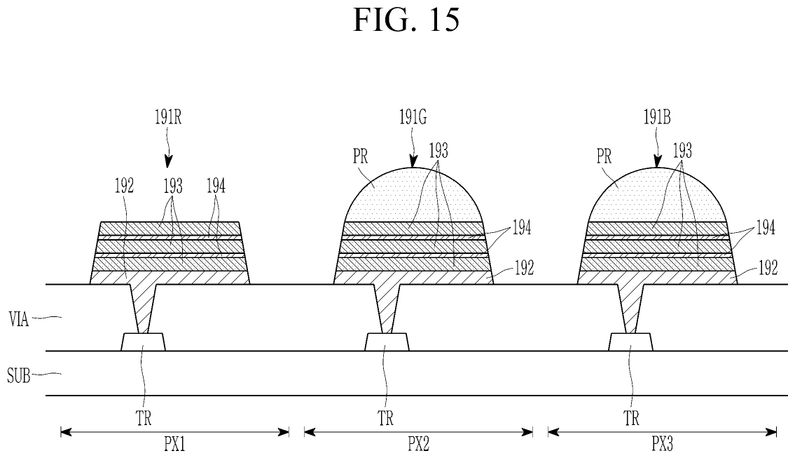

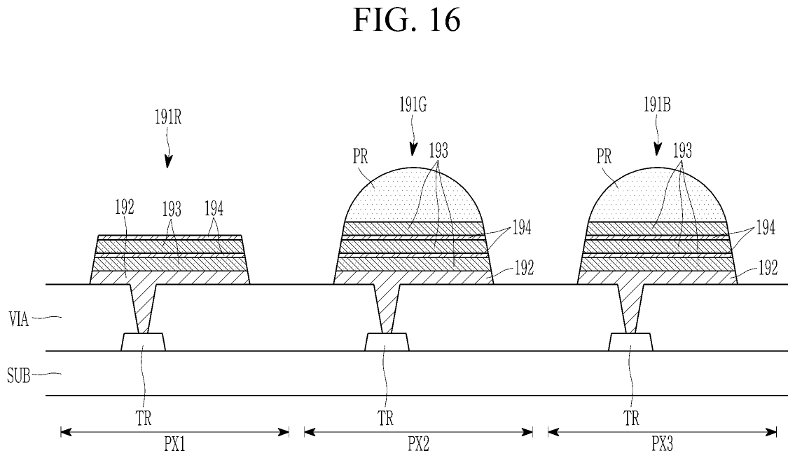

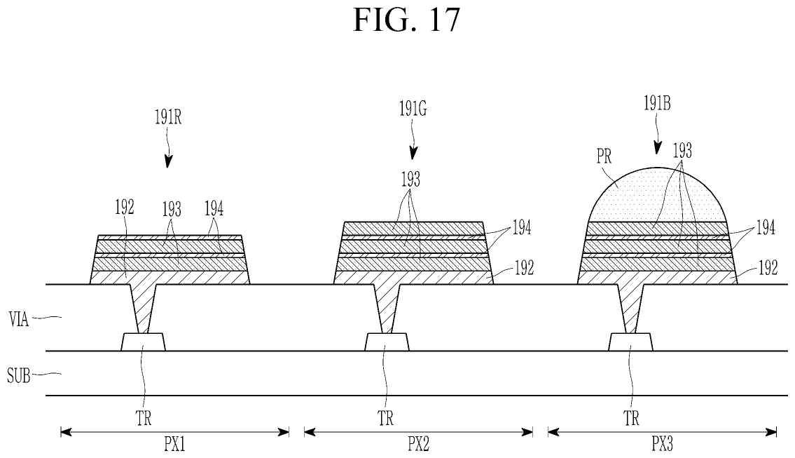

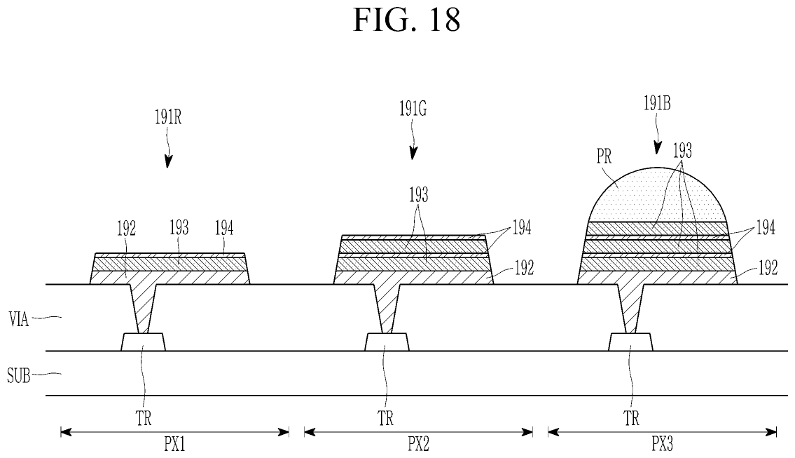

A photoresist PR may be disposed on the first electrodes of some pixels. In FIG. 15, a photoresist may be disposed on the first electrode 191G of the second pixel PX2 and the first electrode 191B of the third pixel PX3. Referring to FIG. 16, the first electrode 191R of the first pixel PX1 not covered by the photoresist PR may be etched. The etching may be performed on the inorganic layer 193 disposed on the etch stop layer 194. Since the etch rate of the etch stop layer 194 may be low, only the inorganic layer 193 may be selectively etched. Referring to FIG. 17, the photoresist on the first electrode 191G of the second pixel PX2 may be removed. Referring to FIG. 18, the first electrode 191R of the first pixel PX1 and the first electrode 191G of the second pixel PX2 not covered by the photoresist PR may be etched.

The etch stop layer 194 and the inorganic layer 193 of the first electrode 191R of the first pixel may be etched by etching. The inorganic layer 193 of the first electrode 191G of the second pixel may be etched. Accordingly, the uppermost layer of the first electrode 191R of the first pixel PX1 and the uppermost layer of the first electrode 191G of the second pixel PX2 become the etch stop layer 194.

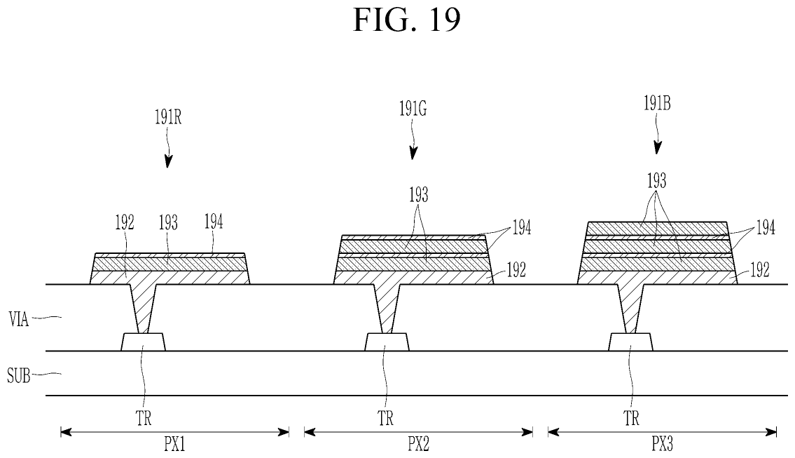

Referring to FIG. 19, the photoresist PR disposed on the first electrode 191B of the third pixel may be removed. As shown in FIG. 19, through this process, the first electrode 191R of the first pixel, the first electrode 191G of the second pixel, and the first electrode 191B of the third pixel having different thicknesses may be formed. As can be seen in FIG. 19, the uppermost layer of the first electrode 191B of the third pixel PX3 having the thickest thickness may be the inorganic layer 193, and the uppermost layers of the first electrodes 191R and 191G of the remaining pixels PX1 and PX2 may be the etch stop layer 194. This may be because the etch stop layer 194 blocks etching during the etch process. Since the etch stop layer 194 may be disposed therebetween, the upper surface of the etched first electrode may be flat and the first electrode may have a uniform thickness.

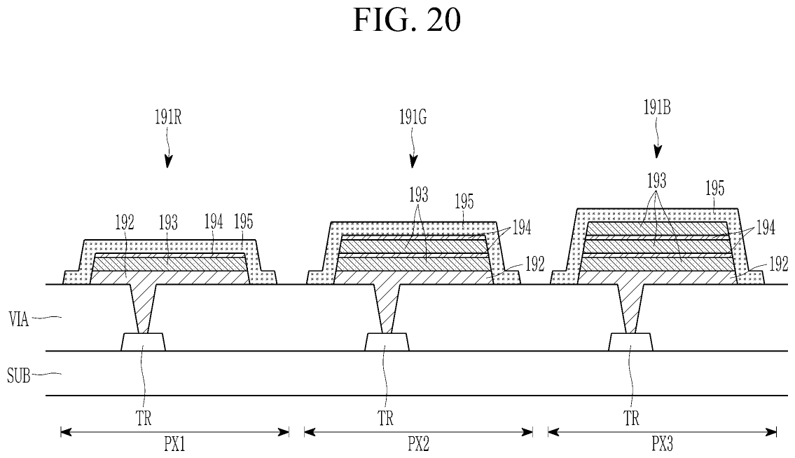

Referring to FIG. 20, the second metal layer 195 may be formed. The second metal layer 195 may be electrically connected to and contact (i.e., directly contact) the first metal layer 192. As described above, in the manufacturing method of the first electrode according to the embodiment, the inorganic layer 193 and the etch stop layer 194 having different etch rates may be alternately deposited and then etched, so that the upper surface of the etched first electrode may be uniform.

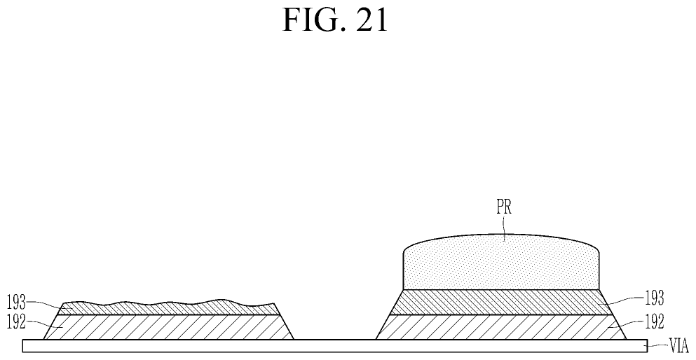

In the case in which the first electrode 191 does not include the etch stop layer 194, the upper surface thereof may not be formed to be flat during the etch process, and it may not have a uniform thickness. FIG. 21 illustrates etching of the first electrode 191 not including the etch stop layer 194. As shown in FIG. 21, in case that only the inorganic layer 193 may be included without the etch stop layer 194, since the degrees of etching in respective areas of the inorganic layer 193 may be different, it may be difficult to control the uniform thickness. FIG. 21 shows a configuration in which the thickness of the inorganic layer 193 may be differently etched in respective areas. In the light emitting element, a change in the thickness of the resonant layer between the first electrode 191 and the second electrode 270 may change the light emitting color of the light emitting element, so uniform thickness control may be very important. However, as shown in FIG. 21, in case that the upper surface of the inorganic layer 193 is not uniform, it may be difficult to control the thickness of the resonance layer.

However, the first electrode 191 according to the embodiment has the structure in which the inorganic layer 193 and the etch stop layer 194 may be sequentially stacked on each other, and the etch stop layer 194 may be disposed as the uppermost layer of the first electrode 191 to be etched. Since the etch stop layer 194 may be a layer that prevents etching, the etching of each step stops at the etch stop layer 194, and the upper surface of the etched first electrode 191 has a uniform surface.

In the display device according to the embodiment, the thickness of the first electrode 191 may be varied for each pixel, so that the resonance thickness of each pixel emitting light of each color may be controlled without adding a separate mask. Accordingly, even in the case of an ultra-high resolution display device, it may be possible to reduce problems in which deposition may not be accurately performed due to mask alignment errors and deposition dispersion, and it may be possible to stably form the display device. The first electrode 191 has the structure in which the inorganic layer and the etch stop layer may be alternately stacked on each other, and the etch stop layer blocks etching during the etching process to form the differential thickness, so the upper surface of the first electrode 191 may be uniformly formed.

While this disclosure has been described in connection with what may be presently considered to be practical embodiments, it may be to be understood that the disclosure may not be limited to the disclosed embodiments, but, on the contrary, may be intended to cover various modifications and equivalent arrangements included within the spirit and scope of the appended claims.

What is claimed is:

1. A display device comprising:
a substrate; and
a first light emitting element, a second light emitting element, and a third light emitting element disposed on the substrate, wherein
each of the light emitting elements includes a first electrode, a light emitting layer, and a second electrode,
the first electrode includes a first metal layer, at least one inorganic layer, at least one etch stop layer, and a second metal layer stacked on each other, and
a thickness of the first electrode of the first light emitting element is different from a thickness of the first electrode of the second light emitting element.

2. The display device of claim 1, wherein the at least one inorganic layer and the at least one etch stop layer are disposed on one another in an alternate manner.

3. The display device of claim 1, wherein a thickest of the first electrode of the first light emitting element, the first electrode of the second light emitting element, and the first electrode of the third light emitting element has one of the at least one inorganic layer as an upper surface that is in direct contact with the second metal layer.

4. The display device of claim 3, wherein at least one of the first electrode of the first light emitting element, the first electrode of the second light emitting element, and the first electrode of the third light emitting element has one of the at least one etch stop layer as an upper surface that is in direct contact with the second metal layer.

5. The display device of claim 1, further comprising
a plurality of transistors disposed on the substrate,
wherein each of the plurality of transistors is electrically connected to the first metal layer.

6. The display device of claim 1, wherein the second metal layer is electrically connected to the first metal layer.

7. The display device of claim 1, wherein an etch rate of each of the at least one etch stop layer is lower than an etch rate of each of the at least one inorganic layer.

8. The display device of claim 1, wherein each of the at least one inorganic layer is thicker than each of the at least one etch stop layer.

9. The display device of claim 1, wherein each of the at least one inorganic layer includes at least one of a silicon nitride (SiNₓ), a silicon oxide (SiOₓ), and a silicon oxynitride (SiOₓN_{y}).

10. The display device of claim 1, wherein each of the at least one etch stop layer includes TiO₂.

11. The display device of claim 1, wherein the light emitting layer includes:
a first light emitting layer disposed in the first light emitting element,
a second light emitting layer disposed in the second light emitting element, and
a third light emitting layer disposed in the third light emitting element.

12. The display device of claim 11, wherein the first light emitting layer, the second light emitting layer, and the third light emitting layer emit light of different colors from each other.

13. The display device of claim 11, wherein the first light emitting layer, the second light emitting layer, and the third light emitting layer each emit light of a same color.

14. The display device of claim 1, wherein at least one of the first light emitting layer, the second light emitting layer, and the third light emitting layer is commonly disposed in each of the first light emitting element, the second light emitting element, and the third light emitting element.

15. The display device of claim 1, further comprising:
a bank disposed between ones of the first light emitting element, the second light emitting element, and the third light emitting element, the bank partitioning a light emitting area, wherein
a length of a light emitting area of each of the first light emitting element, the second light emitting element, and the third light emitting element is in a range of about 2 μm to about 8 μm, and
a width of a light emitting area of each of the first light emitting element, the second light emitting element, and the third light emitting element is in a range of about 2 μm to about 4 μm.

16. The display device of claim 15, wherein areas of the light emitting areas of the first light emitting element, the second light emitting element, and the third light emitting element are different from each other.

17. A method of manufacturing a display device, the method comprising:
forming a plurality of first metal layers on a substrate;
forming a stack of at least one inorganic layer and at least one etch stop layer disposed on one another in an alternate manner on the plurality of first metal layers;
disposing a photoresist on a portion of the stack; and
etching one of the at least one inorganic layer on portions of the stack absent of the photoresist.

18. The method of claim 17, wherein in the forming of the stack of the at least one inorganic layer and the at least one etch stop layer disposed on one another in an alternate manner on the plurality of first metal layers, one of the at least one inorganic layer is disposed on an uppermost surface of the stack.

19. The method of claim 17, wherein in the etching of the one of the at least one inorganic layer of the portion of the stack absent the photoresist, one of the at least one etch stop layer is disposed on an uppermost surface of the etched stack.

20. The method of claim 17, wherein an etch rate of each of the at least one etch stop layer is lower than an etch rate of each of the at least one inorganic layer.

21. The method of claim 17, wherein each of the at least one inorganic layer is thicker than each of the at least one etch stop layer.

22. The method of claim 17, wherein each of the at least one inorganic layer includes at least one of a silicon nitride (SiNₓ), a silicon oxide (SiOₓ), and a silicon oxynitride (SiOₓN_{y}).

23. The method of claim 17, wherein each of the at least one etch stop layer includes TiO₂.

24. The method of claim 17, further comprising:
forming a second metal layer on the stack,
wherein the second metal layer is directly connected to the first metal layer.
